(19) United States
(12) Patent Application Publication
(10) Pub. No.: US 2026/0309769 A1
(43) Pub. Date: Oct. 8, 2026

(54) PROBE STATION DEVICE

(71) Applicants: Mi Ryeong CHO, Gyeonggi-do (KR); KOREA BASIC SCIENCE INSTITUTE, Daejeon (KR)

(72) Inventors: Seung Young PARK, Daejeon (KR); Yeon Suk CHOI, Daejeon (KR); Jisung LEE, Daejeon (KR); Myang Su KIM, Hwaseong-si Gyeonggi-do (KR)

(21) Appl. No.: 19/484,830

(22) PCT Filed: Jul. 5, 2024
(86) PCT No.: PCT/KR2024/009590

§ 371 Date: Nov. 14, 2025

(30) Foreign Application Priority Data
Aug. 9, 2023 (KR) 10-2023-0104241

(51) Int. Cl. G01R 31/28

(52) U.S. Cl. CPC G01R 31/2862; G01R 31/2867; G01R 31/2877

(57) ABSTRACT

A probe station device according to one embodiment comprises: a sample stage on which a specimen is placed; a refrigerator which is disposed below the sample stage and which controls the temperature of the sample stage; a mounting part which is disposed below the refrigerator and which supports the refrigerator; a first chamber for encompassing the outside of the sample stage; a second chamber of which the inside is maintained in a vacuum state and which encompasses the outside of the first chamber; and a vibration-reducing member that connects the refrigerator to the second chamber, wherein the sample stage, the first chamber and the second chamber can be connected to each other.

### TECHNICAL FIELD

The present disclosure relates to a probe station device.

### BACKGROUND ART

A conduction-cooled probe station device is a device used to analyze electrical characteristics of electric components, semiconductor devices, and the like with a function of temperature. In the semiconductor industry, for example, it is used to measure and test characteristics of semiconductor devices at high temperatures. It is also used in various fields, such as nanotechnology, material research, and optical equipment, in experiments and measurements that require heat transfer and temperature control.

A conduction-cooled probe station device performs cooling by conducting heat to provide a stable operating environment.

Vibration occurs due to the movement of gas and the reciprocating piston motion of the refrigerator in the conduction-cooled probe station device, and the generated vibration is transferred to a stage, causing problems such as mechanical friction of a probe needle, reduced resolution of an optical microscope, and the like.

### DISCLOSURE OF THE INVENTION

### Technical Goals

An object according to an embodiment is to provide a probe station device that suppresses vibration generated in a refrigerator from being transmitted to a stage.

### Technical Solutions

A probe station device according to an embodiment includes a sample stage on which a specimen is placed, a refrigerator disposed below the sample stage and configured to control temperature of the sample stage, a mounting portion disposed below the refrigerator and configured to support the refrigerator, a first chamber configured to surround an outside of the sample stage, a second chamber configured to maintain a vacuum state inside and surround an outside of the first chamber, and a vibration reduction member configured to connect the refrigerator to the second chamber, wherein the sample stage, the first chamber, and the second chamber may be connected to each other.

The probe station device according to an embodiment may further include a first supporter configured to connect the sample stage to the first chamber and a second supporter disposed between the first chamber and the second chamber and configured to connect the first chamber to the second chamber.

According to an embodiment, the first supporter may be fixed to the sample stage in a state of being spaced apart from the sample stage.

According to an embodiment, the sample stage may be connected to the first chamber and the second chamber via the first supporter and the second supporter and be capable of receiving a load of the first chamber and the second chamber.

The probe station device according to an embodiment may further include a connector formed on an inner wall of the second chamber, wherein the connector and part of the second supporter may be interlocked with each other, and wherein part of the sample stage and part of the first supporter may be interlocked with each other.

According to an embodiment, the first chamber may include a side wall disposed between the first supporter and the second supporter and configured to surround a circumference of the sample stage, a cover supported by the side wall, and an observation element disposed on the cover and capable of monitoring the sample stage, wherein the cover may be provided to be movable with respect to the side wall.

According to an embodiment, the first chamber may further include a base extending from a lower end of the side wall, wherein a gap may be present between the base and an outer wall of the refrigerator, and wherein the base may be connected to the outer wall of the refrigerator via a first heat conduction link.

According to an embodiment, the cover may be connected to the side wall via a second heat conduction link.

According to an embodiment, the first heat conduction link may be formed of copper or aluminum.

According to an embodiment, the first heat conduction link may be formed of one of a single or a plurality of wire rod(s), a braided wire made of wire rods, or a stranded wire having a twisted shape.

The probe station device according to an embodiment may further include a bridge configured to connect the first supporter to the second supporter.

According to an embodiment, the bridge may be configured to support the side wall of the first chamber.

According to an embodiment, the bridge may be provided in plurality along the circumference of the sample stage, centered on the sample stage.

According to an embodiment, the connector may be provided in plurality along the inner wall of the second chamber.

According to an embodiment, the second supporter may include a supporter body supported by the side wall of the first chamber and a plurality of supporter protrusions formed to extend from the supporter body toward the second chamber.

According to an embodiment, each of the plurality of supporter protrusions may pass between two adjacent connectors among the plurality of connectors.

The probe station device according to an embodiment may further include a plurality of supporter holes formed through the first supporter or the second supporter.

According to an embodiment, the plurality of supporter holes may be formed in a first direction, which may be a height direction of a side wall of the first chamber, or formed in a second direction intersecting the first direction.

According to an embodiment, a shape of a supporter hole formed through the first supporter may be different from a shape of a supporter hole formed through the second supporter.

According to an embodiment, the vibration reduction member may be a damper or a bellows.

The probe station device according to an embodiment may further include an optical table disposed on a ground and configured to support the second chamber, wherein the sample stage, the first chamber, the second chamber, and the optical table may be connected to each other.

A probe station device according to an embodiment includes a refrigerator disposed below the sample stage and configured to control temperature of the sample stage, a mounting portion disposed below the refrigerator and supported by a ground, a stage supporter connected to the mounting portion and configured to support the sample stage, a first chamber surrounding an outside of the sample stage, a second chamber configured to maintain a vacuum state inside and surround an outside of the first chamber, and a vibration reduction member configured to connect the refrigerator to the second chamber, wherein the sample stage may be capable of receiving a load of the mounting portion through the stage supporter.

### Effects of the Invention

A probe station device according to an embodiment may suppress vibration generated in a refrigerator from being transferred to a stage.

### BRIEF DESCRIPTION OF DRAWINGS

FIG. 1 is a front view schematically illustrating a probe station device according to an embodiment.

FIG. 2 is a front view schematically illustrating an interior of a first chamber and a second chamber, according to an embodiment.

FIG. 3 is a plan view schematically illustrating an interior of a first chamber and a second chamber, according to an embodiment.

FIG. 4 is a plan view schematically illustrating a first supporter, a second supporter, and a supporter hole, according to an embodiment.

FIG. 5 is a plan view schematically illustrating a first supporter, a second supporter, and a supporter hole, according to an embodiment.

FIG. 6 is a front view schematically illustrating an interior of a first chamber and a second chamber, according to an embodiment.

FIG. 7 is a plan view schematically illustrating a second chamber, a connector, and a second supporter, according to an embodiment.

FIG. 8 is a plan view schematically illustrating a second chamber, a connector, and a second supporter, according to an embodiment.

FIG. 9 is a plan view schematically illustrating a first supporter, a second supporter, and a bridge, according to an embodiment.

FIG. 10 is a front view schematically illustrating a probe station device according to an embodiment.

FIG. 11 is a front view schematically illustrating a mounting portion, a leg of an optical table, and spacers, according to an embodiment.

### BEST MODE FOR CARRYING OUT THE INVENTION

The following detailed structural or functional description is provided as an example only and various alterations and modifications may be made to the embodiments. Thus, an actual form of implementation is not construed as limited to the embodiments described herein and should be understood to include all changes, equivalents, and replacements within the idea and the technical scope of the disclosure.

Although terms such as first, second, and the like may be used to describe various components, the components are not limited to the terms. These terms should only be used to distinguish one component from another component. For example, a “first” component may be referred to as a “second” component, and similarly, the “second” component may be referred to as the “first” component.

It should be noted that if one component is described as being “connected,” “coupled,” or “joined” to another component, the first component may be directly connected, coupled, or joined to the second component, or a third component may be “connected,” “coupled,” or “joined” between the first and second components.

The singular forms “a,” “an,” and “the” used herein are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

The same name may be used to describe components having the same function, which are included in different embodiments. Unless otherwise mentioned, the description of one embodiment may be applicable to other embodiments. Thus, repeated description is omitted for conciseness.

Unless otherwise defined, all terms used herein including technical and scientific terms have the same meanings as those commonly understood by one of ordinary skill in the art to which this disclosure pertains. Terms such as those defined in commonly used dictionaries are to be interpreted as having a meaning that is consistent with their meaning in the context of the relevant art and are not to be interpreted in an idealized or overly formal sense unless expressly so defined herein.

Hereinafter, the embodiments are described in detail with reference to the accompanying drawings. When describing the embodiments with reference to the accompanying drawings, like reference numerals refer to like components and a repeated description related thereto is omitted.

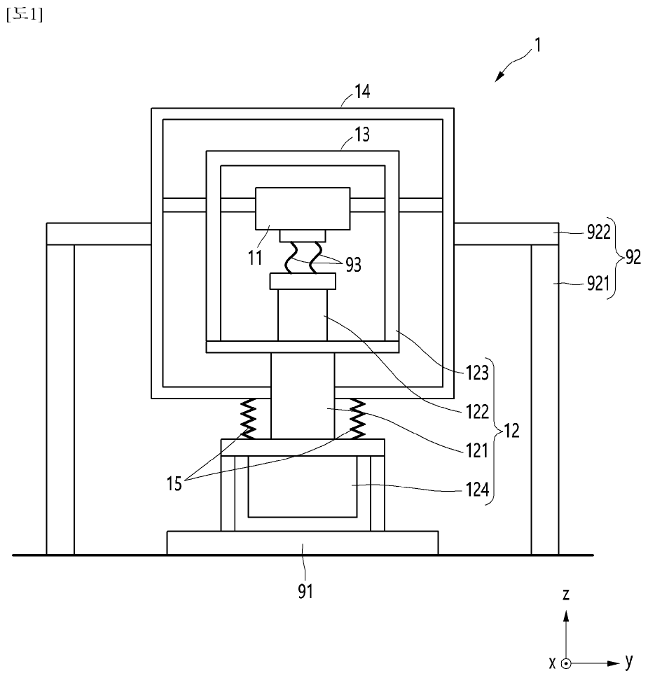

FIG. 1 is a front view schematically illustrating a probe station device according to an embodiment.

Referring to FIG. 1, a probe station device 1 according to an embodiment may measure and test characteristics of a specimen placed on a sample stage 11. The probe station device 1 may reduce an amount of vibration generated in a refrigerator 12 and transmitted to the sample stage 11 by maximizing a respective mass of the sample stage 11 and the refrigerator 12. The probe station device 1 may include the sample stage 11, the refrigerator 12, a mounting portion 91, a first chamber 13, a second chamber 14, and an optical table 92.

A specimen may be placed on the sample stage 11. The refrigerator 12 may be disposed below the sample stage 11 and control a temperature of the sample stage 11. The refrigerator 12 may include a closed-cycle refrigerator (CCR) first stage 121, a CCR second stage 122, a refrigerator outer wall 123, and a motor 124.

The CCR first stage 121 may compress a refrigerant. For example, the CCR first stage 121 may include a compressor. The refrigerant compressed through the CCR first stage 121 may be maintained in a liquid state as pressure thereof increases.

The CCR second stage 122 may perform cooling by removing heat from the compressed refrigerant and evaporating the refrigerant. For example, the CCR second stage 122 may include a condenser and an expansion device. The condenser may discharge the heat of the compressed refrigerant and convert the refrigerant into a liquid state. The expansion device may reduce the pressure of the refrigerant that is in a liquid state.

The CCR second stage 122 may be connected to the sample stage 11 via a CCR heat conduction link 93. The CCR heat conduction link 93 may include, for example, an elastic body and a damper. The CCR heat conduction link 93 may reduce the temperature of the sample stage 11 by taking heat from the sample stage 11.

The refrigerator outer wall 123 may cover the side of the CCR heat conduction link 93 and the CCR second stage 122 while being supported by the CCR first stage 121. The refrigerator outer wall 123 may reduce an amount of air flowing in around the CCR heat conduction link 93 and the CCR second stage 122 from the outside. The outer wall of the refrigerator 123 may reduce interference from outside air and reduce heat intrusion by radiant heat from the outside while the temperature of the sample stage 11 is controlled. The refrigerator outer wall 123 may also be referred to as a ‘heat shield.’

The motor 124 may provide power to the CCR first stage 121 and the CCR second stage 122. Here, vibration may occur when the motor 124 is driven, or vibration may occur when the refrigerant moves to the CCR first stage 121 and the CCR second stage 122.

The mounting portion 91 may be disposed below the refrigerator 12 and may support the refrigerator 12. One surface of the mounting portion 91 may be supported on the ground. The refrigerator 12 may be connected to the mounting portion 91 and receive a load of the mounting portion 91. The mass of the refrigerator 12 may increase, and the vibration generated in the refrigerator 12 may be reduced. By connecting an additional weight to the mounting portion 91, a weight of the mounting portion 91 may be increased.

The first chamber 13 may surround an outside of the sample stage 11. The first chamber 13 may maintain an interior thereof at a constant temperature. For example, an interior temperature of the first chamber 13 may be 100 kelvin (K) or less, for example, 4.2 K. The sample stage 11 may be connected to the first chamber 13 and receive a load of the first chamber 13.

The second chamber 14 may maintain a vacuum state inside and surround an outside of the first chamber 13. The second chamber 14 may maintain an interior thereof at a constant temperature. For example, an interior temperature of the second chamber 14 may be 30 K to 300 K. The first chamber 13 may be connected to the second chamber 14 and receive a load of the second chamber 14. In this structure, the sample stage 11 may receive the load of not only the first chamber 13 but also the second chamber 14.

The second chamber 14 may be connected to the refrigerator 12 via a vibration reduction member 15. The vibration reduction member 15 may absorb some of the vibration generated in the refrigerator 12, thereby reducing the amount of vibration transmitted to the chamber. The vibration reduction member 15 may be, for example, a damper or a bellows.

The optical table 92 may include a leg 921 disposed on the ground and a top plate 922 connected to the leg 921 and supporting the second chamber 14. The sample stage 11, the first chamber 13, the second chamber 14, and the optical table 92 may be connected to each other. The sample stage 11 may receive a load of the optical table 92 as well as the load of the first chamber 13 and the second chamber 14.

Although not shown in the drawings, vibration dampening feet may additionally be provided on the leg 921 of the optical table 92, which may contact the ground. Vibration occurring in the optical table 92 due to an external impact of the probe station device 1 may be reduced, and noise occurring during an operation of the probe station device 1 may be reduced.

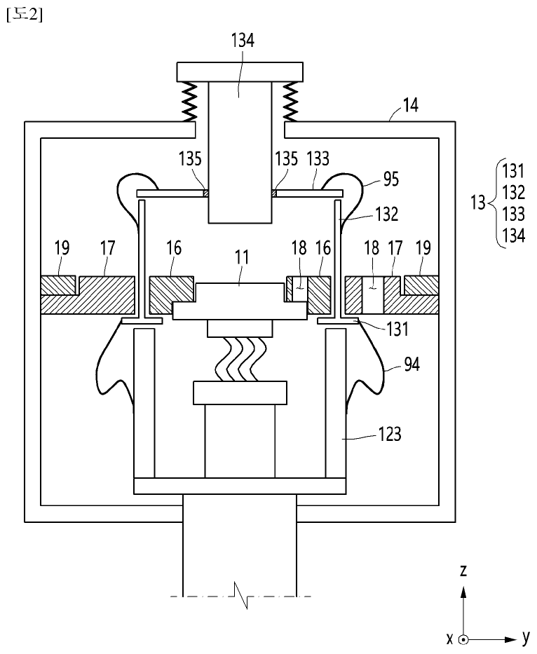

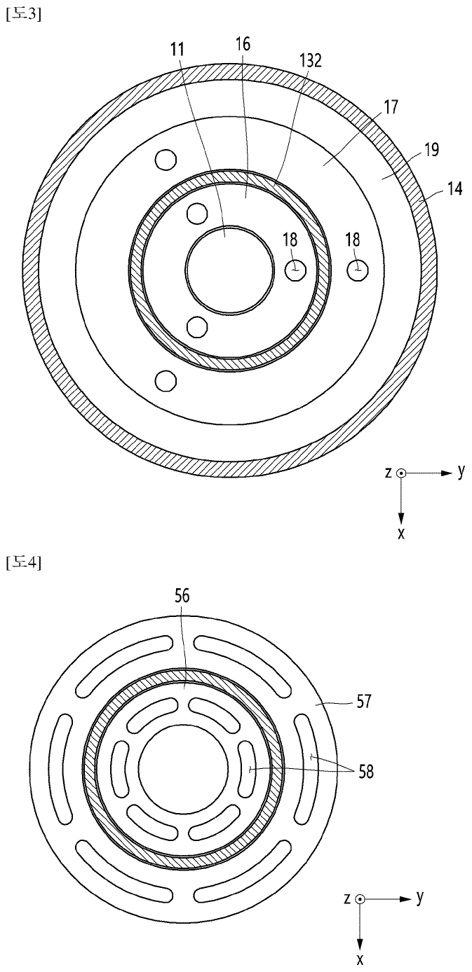

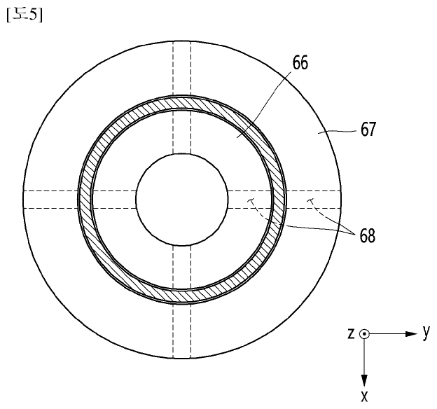

FIG. 2 is a front view schematically illustrating an interior of a first chamber and a second chamber, according to an embodiment, and FIG. 3 is a plan view schematically illustrating an interior of a first chamber and a second chamber according to an embodiment. FIGS. 4 and 5 are plan views each schematically illustrating a first supporter, a second supporter, and a supporter hole, according to an embodiment.

Referring to FIGS. 2 and 3, the sample stage 11 according to an embodiment may be connected to the first chamber 13 via a first supporter 16, and the first chamber 13 may be connected to the second chamber 14 via a second supporter 17. The sample stage 11 may receive the load of the first chamber 13 and the second chamber 14 through the first supporter 16 and the second supporter 17.

Part of the first supporter 16 and part of the sample stage 11 may be interlocked with each other. For example, as shown in FIG. 2, the sample stage 11 may have a shape in which a center portion thereof protrudes upward. Here, upward may be a +z direction. The first supporter may have a ring shape with a perforated center, and an upper portion of the first supporter 16 may protrude toward the center portion of the sample stage 11. When the protruding center portion of the sample stage 11 is inserted into the perforated center of the first supporter 16, the first supporter 16 may be supported by an edge of the sample stage 11. A lower portion of the first supporter 16 may be supported by the first chamber 13.

Alternatively, the sample stage 11 and the first supporter 16 may be mechanically coupled while being spaced apart from each other. For example, a gap may be present between the edge of the sample stage 11 and the first supporter 16. Due to this structure, heat conducted from the first supporter 16 to the sample stage 11 may be reduced. The second supporter 17 may be disposed between the first chamber 13 and the second chamber 14 to connect the first chamber 13 to the second chamber 14. A lower portion of the second supporter 17 may protrude toward an inner wall of the second chamber 14 and be interlocked with a connector 19 formed on the inner wall of the second chamber 14. The part at which the second supporter 17 and the connector 19 are interlocked may be connected with a screw.

In an embodiment, the first supporter 16 and the second supporter 17 may be formed of a material that is crack-free at an extremely low temperature and has low heat conductivity. For example, the first supporter 16 and the second supporter 17 may be formed of a fiber reinforced resin composite material such as glass fiber epoxy resin.

The connector 19 may be formed to protrude along a perimeter of the inner wall of the second chamber 14. The connector 19 may be formed continuously along the perimeter of the inner wall of the second chamber 14. Due to this structure, the second supporter 17 may have an upward movement thereof restricted by the connector 19 and a downward movement thereof restricted by the first chamber 13.

To prevent heat of the first chamber 13 from being transferred to the sample stage 11, the first supporter 16 may be formed of a material having low heat conductivity. Likewise, to prevent heat of the second chamber 14 from being transferred to the first chamber 13, the second supporter 17 may be formed of a material having low heat conductivity.

A plurality of supporter holes 18 may be formed through the first supporter 16 and the second supporter 17 in a height direction of the first chamber 13, along a circumference based on the center. For example, the plurality of supporter holes 18 may be formed spaced apart from each other at equal intervals. Heat conducted from the outside of the second chamber 14 to the inside of the first chamber 13 through the first supporter 16 and the second supporter 17 may be reduced. An insulation effect of the first chamber 13 and the second chamber 14 may be increased.

In addition, it should be noted that the shape and number of the plurality of holes 18 are not limited to the shape and number of the holes 18 illustrated in FIG. 3. The plurality of holes may have a single or multiple type(s) of shapes that may minimize heat conduction, such as a circular, elliptical, spiral, or radial shape.

For example, as illustrated in FIG. 4, a plurality of supporter holes 58 according to an embodiment may be formed lengthwise in a first supporter 56 and a second supporter 57, respectively, centered on the sample stage 11 along the circumference thereof. For example, as illustrated in FIG. 5, a plurality of supporter holes 68 according to an embodiment may each be formed to penetrate a first supporter 66 and a second supporter 67 in a horizontal direction rather than a vertical direction.

In an embodiment, to reduce vibration generated in a refrigerator and transmitted to the sample stage 11, the first chamber 13 and the refrigerator outer wall 123 may be separated from each other. Vibration generated in the refrigerator and transmitted to the first chamber 13 may be reduced. The first chamber 13 may include a base 131, a side wall 132, a cover 133, and an observation element 134.

The base 131 may support the lower portion of the first supporter 16 and the lower portion of the second supporter 17, respectively. A gap may be present between the base 131 and the refrigerator outer wall 123. The base 131 may be connected to the refrigerator outer wall 123 via a first heat conduction link 94.

Similarly to the CCR heat-conducting link 93, the first heat conduction link 94 may be formed of a flexible, highly heat-conductive material. For example, the CCR heat conduction link 93 and the first heat conduction link 94 may be a single or a plurality of thin and long wire rod(s), a braided wire made of wire rods, or a stranded wire having a twisted shape. For example, the CCR heat conduction link 93 and the first heat conduction link 94 may be formed of a metal such as copper or aluminum.

The refrigerator outer wall 123 and the side wall 132 of the first chamber 13 may be connected by the first heat conduction link 94, and therefore, vibration transmitted from the refrigerator outer wall 123 to the side wall 132 of the first chamber 13 may be reduced. A cooler may remove heat from the interior of the first chamber 13 via the first heat conduction link 94 and maintain the interior temperature of the first chamber 13 constant.

The side wall 132 may be formed to extend upward from the base 131. The side wall 132 may be disposed between the first supporter 16 and the second supporter 17 and surround the circumference of the sample stage 11. The side wall 132 may prevent heat intrusion by radiant heat from the outside. The side wall 132 may be formed of, for example, aluminum.

The cover 133 may be supported with respect to the side wall 132. The cover 133 may move in the horizontal direction with respect to the side wall 132. Here, the horizontal direction may be a direction parallel to the y-axis. The cover 133 may be connected to the side wall 132 via a second heat conduction link 95. The second heat conduction link 95 may be formed of a flexible, highly heat-conductive material. For example, the second heat conduction link 95 may be formed of the same material as the first heat conduction link 94. For example, the second heat conduction link 95 may be formed of a metal such as copper or aluminum. Heat of the cover 133 may be transferred to the side wall 132 via the second heat conduction link and subsequently to the refrigerator via the first heat conduction link 94. Heat diffusion into the first chamber 13 via the cover 133 may be reduced.

For reference, it should be noted that the CCR heat conduction link 93, the first heat conduction link 94, and the second heat conduction link 95 may each be provided in plurality and disposed in respective sections.

The observation element 134 may face the sample stage 11 while being disposed on the cover 133. As the cover 133 moves horizontally with respect to the side wall 132, the observation element 134 may also move integrally with the cover 133. In addition to monitoring of the sample stage 11 through the observation element 134, a wide range of optical experiments may be performed, such as magnified observation of a specimen image, analysis of reflection lights after injecting optical energy such as a laser, and the like. A cover sealing element 135 may be disposed between the observation element 134 and the cover 133. The cover sealing element 135 may reduce heat penetrating from a second chamber 34 into a first chamber 33 and reduce frost generated on a surface of the observation element 134.

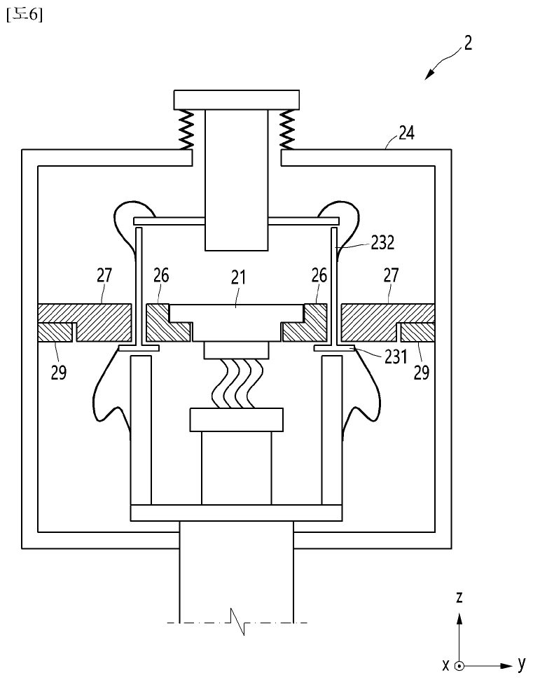

FIG. 6 is a front view schematically illustrating an interior of a first chamber and a second chamber, according to an embodiment.

Referring to FIG. 6, a center portion of a sample stage 21 of a probe station device 2 according to an embodiment may protrude downward. The lower portion of the first supporter 26 may protrude toward the center portion of the sample stage 21 and support an edge of the sample stage 21. The lower portion of the first supporter 26 may be supported by a base 231 of the first chamber.

An upper portion of a second supporter 27 may be formed to protrude toward an inner wall of a second chamber 24. A connector 29 may support the second supporter 27 from below. Unlike the probe station device illustrated in FIG. 2, when assembling the probe station device 2 illustrated in FIG. 6, the assembly process may be simplified because each component may be assembled by stacking from the bottom. For example, when assembling the probe station device 2 illustrated in FIG. 6, the first supporter 26 may be first disposed, while the cover is removed, within the side wall 232 of the first chamber so that the first supporter 26 may be supported by the base 231 of the first chamber, and the sample stage 21 may be disposed on top of the first supporter 26. Likewise, the second supporter 27 may be disposed to be supported by the connector 29 and the base 231 of the first chamber.

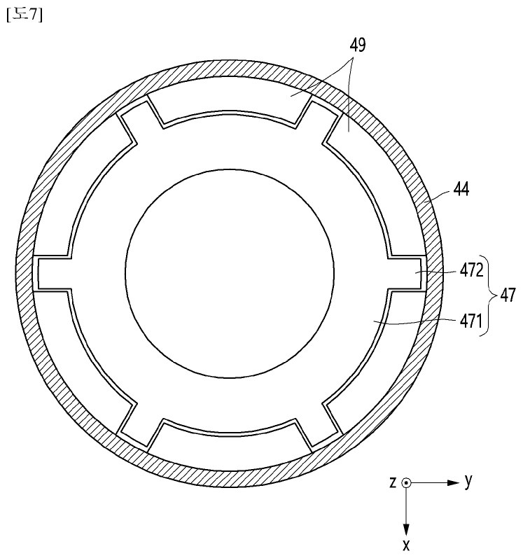

FIGS. 7 and 8 are plan views schematically illustrating a second chamber, a connector, and a second supporter, according to an embodiment.

Referring to FIGS. 7 and 8, a plurality of connectors 49 according to an embodiment may be provided. The connectors 49 may be formed discontinuously along a perimeter of an inner wall of a second chamber 44. A second supporter 47 may be screw-connected to the connectors 49 after passing through a gap between the connectors 49. In a process of assembling a probe station device, the second supporter 47 may be connected to the second chamber 44 regardless of the assembly order between the second chamber 44 and the second supporter 47. For example, the second chamber 44 may be disposed first and then the second supporter 47 may be connected to the connectors 49, or the second supporter 47 may be disposed first and then the connectors 49 may be connected to the second supporter 47. Likewise, in a process of disassembling the probe station device, the second supporter 47 may be separated from the second chamber 44 regardless of the disassembly order between the second chamber 44 and the second supporter 47.

The second supporter 47 may include a supporter body 471 supported by a side wall of a first chamber, and a plurality of supporter protrusions 472 formed to extend from the supporter body 471 toward the second chamber 44. For example, the supporter body 471 may have a ring shape with a hole through a center thereof, and the supporter protrusions 472 may protrude in a circumferential direction from the supporter body 471.

Each of the plurality of supporter protrusions 472 may pass between two adjacent connectors 49 among the plurality of connectors 49. In this structure, when the supporter protrusions 472 pass between the connectors 49 and the second supporter 47 rotates in one direction, the supporter protrusions 472 may overlap the connectors 49 with respect to the z-axis direction. Each of the supporter protrusions 472 may be screw-connected to each of the overlapping connectors 49.

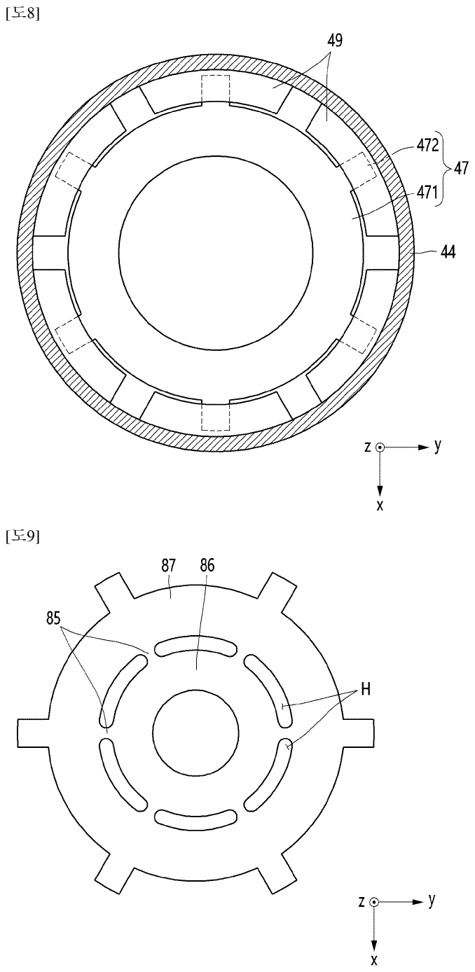

FIG. 9 is a plan view schematically illustrating a first supporter, a second supporter, and a bridge, according to an embodiment.

Referring to FIG. 9, a probe station device according to an embodiment may further include a bridge 85. The bridge 85 may connect a first supporter 86 to a second supporter 87. The first supporter 86, the second supporter 87, and the bridge 85 may be connected to each other to have an integrated structure. The bridge 85 may be formed of, for example, the same material as the first supporter 86 and the second supporter 87.

The bridge 85 may be provided in plurality around a sample stage along a circumference thereof. A side wall of the first chamber may be supported by each of the bridges 85 and a portion of the side wall may be extended to pass through a hole H surrounded by the two adjacent bridges 85, the first supporter 86, and the second supporter 87. The side wall of the first chamber passing through the hole H may be connected to a refrigerator outer wall through a first heat conduction link.

In an embodiment, an area of the hole H may be greater than an area of the bridge 85. As the area of the hole H increases and the area of the bridge 85 decreases, an amount of heat conducted from the second supporter 87 to the first supporter 86 may decrease.

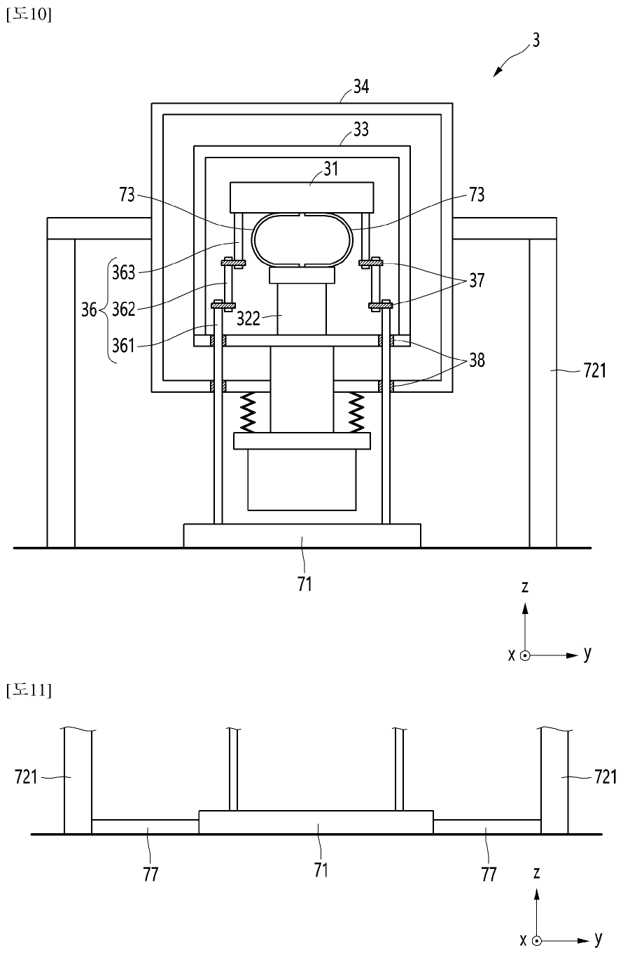

FIG. 10 is a front view schematically illustrating a probe station device according to an embodiment.

Referring to FIG. 10, a sample stage 31 of a probe station device 3 according to an embodiment may receive a load of a mounting portion 71 through a stage supporter 36. The stage supporter 36 may support a lower portion of the sample stage 31 while being connected to the mounting portion 71 supported on the ground. Due to this structure, the sample stage 31 may be physically separated from a refrigerator in which vibration is generated.

In an embodiment, the stage supporter 36 may include a plurality of frames. For example, the stage supporter 36 may include a first frame 361 that is supported by an upper portion of the mounting portion 71 and extending upward, a second frame 362 that is connected to the first frame 361 and extending upward, and a third frame 363 that is connected to the second frame 362, extending upward, and connected to the lower portion of the sample stage 31.

An upper portion of the first frame 361 and a lower portion of the second frame 362 may be coupled by a coupler 37 so that movement thereof relative to each other may be restricted. Likewise, an upper portion of the second frame 362 and a lower portion of the third frame 363 may also be coupled by the coupler 37 so that movement thereof relative to each other may be restricted.

The first frame 361 may penetrate the first chamber 33 and the second chamber 34. A chamber sealing element 38 may be positioned between the first frame 361 and the second chamber 34 and reduce heat penetrating into the second chamber 34 from the outside. Likewise, the chamber sealing element 38 may be positioned between the first frame 361 and the first chamber 33 and reduce heat penetrating into the first chamber 33 from the second chamber 34.

In order to level the sample stage 31 with respect to the ground, the first frame 361, the second frame 362, the third frame 363, and the coupler 37 may each be provided in plurality.

A CCR second stage 322 may be connected to the sample stage 31 via a CCR heat conduction link 73. The CCR heat conduction link 73 may cool a temperature of the sample stage 31 to a cryogenic temperature. For example, the CCR heat conduction link 73 may be provided in two pieces. The two CCR heat conduction links 73 may generate a phase difference, thereby canceling out an amplitude of a vibration waveform generated in the refrigerator.

FIG. 11 is a front view schematically illustrating a mounting portion, a leg of an optical table, and spacers, according to an embodiment.

Referring to FIG. 11, a probe station device according to an embodiment may align a side wall of a first chamber and a refrigerator outer wall in the z-axis direction using a spacer 77. Since the side wall of the first chamber (e.g., the side wall 132 of the first chamber 13 of FIG. 2) and the refrigerator outer wall (e.g., the refrigerator outer wall 123 of FIG. 2) may be spaced apart from each other, when the side wall of the first chamber and the refrigerator outer wall are not aligned with each other, heat-blocking efficiency may decrease or tension may be applied to a first heat conduction link and a CCR heat conduction link.

The spacer 77 may assist in positioning a mounting portion (e.g., the mounting portion 91 of FIG. 1 and the mounting portion 71 of FIG. 10) at a center of a plurality of legs of an optical table (e.g., the leg 921 of the optical table of FIG. 1 and a leg 721 of an optical table of FIG. 10). For example, the number of spacers 77 may be provided equal to the number of the legs 721 and 921 of the optical table, and a length of each of the spacers 77 may be equal to each other.

After the optical table is disposed on the ground, one end of the plurality of spacers 77 may each be connected to the legs 721 and 921 of the optical table. An other end of the spacers 77 may be placed toward a center of the legs 721 and 921 of the optical table. In this state, the mounting portion 71 may be disposed at a position at which the other ends of the spacers 77 meet, and the other ends of the spacers 77 may be connected to the mounting portions 71 and 91.

With the other ends of the plurality of spacers 77 all connected to the mounting portion 71 and 91, the mounting portions 71 and 91 may be disposed at the center of the legs 721 and 921 of the optical table. In addition, the center may be marked on a top plate of the optical table supporting the first chamber and the second chamber, so the side wall of the first chamber may always be disposed at the center of the optical table. When the mounting portions 71 and 91 are disposed at the center of the legs 721 and 921 of the optical table, the side wall 132 of the first chamber and the refrigerator outer wall 123 may be aligned with each other in the z-axis direction.

In an embodiment, the spacer 77 may be removably connected to the legs 721 and 921 and the mounting portions 71 and 91 of the optical table, respectively. After placing the mounting portions 71 and 91 on the ground and before operating the probe station device, the spacer 77 may be removed from the probe station device.

In addition, unlike the illustration of the drawings of this specification, the spacer 77 may be formed of a plurality of segments. Each of the plurality of segments forming the spacer 77 may be removably connected to one another. By controlling a presence or absence of coupling between the plurality of segments and a coupling strength, vibration transmitted from the mounting portions 71 and 91 to the legs 721 and 921 of the optical table may be controlled.

While the embodiments are described with reference to a limited number of drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or substituted by other components or their equivalents.

Therefore, other implementations, other embodiments, and equivalents to the claims are also within the scope of the following claims.

1. A probe station device comprising:
a sample stage on which a specimen is placed;
a refrigerator disposed below the sample stage and configured to control temperature of the sample stage;
a mounting portion disposed below the refrigerator and configured to support the refrigerator;
a first chamber configured to surround an outside of the sample stage;
a second chamber configured to maintain a vacuum state inside and surround an outside of the first chamber; and
a vibration reduction member configured to connect the refrigerator to the second chamber,
wherein the sample stage, the first chamber, and the second chamber are connected to each other.

2. The probe station device of claim 1, further comprising:
a first supporter configured to connect the sample stage to the first chamber; and
a second supporter disposed between the first chamber and the second chamber and configured to connect the first chamber to the second chamber.

3. The probe station device of claim 2, wherein
the first supporter is fixed to the sample stage in a state of being spaced apart from the sample stage.

4. The probe station device of claim 2, wherein
the sample stage is connected to the first chamber and the second chamber via the first supporter and the second supporter and capable of receiving a load of the first chamber and the second chamber.

5. The probe station device of claim 2, further comprising:
a connector formed on an inner wall of the second chamber,
wherein the connector and part of the second supporter are interlocked with each other, and
wherein part of the sample stage and part of the first supporter are interlocked with each other.

6. The probe station device of claim 5, wherein the first chamber comprises:
a side wall disposed between the first supporter and the second supporter and configured to surround a circumference of the sample stage;
a cover supported by the side wall; and
an observation element disposed on the cover and capable of monitoring the sample stage,
wherein the cover is provided to be movable with respect to the side wall.

7. The probe station device of claim 6, wherein the first chamber further comprises a base extending from a lower end of the side wall,
wherein a gap is present between the base and an outer wall of the refrigerator, and
wherein the base is connected to the outer wall of the refrigerator via a first heat conduction link.

8. The probe station device of claim 6, wherein
the cover is connected to the side wall via a second heat conduction link.

9. The probe station device of claim 7, wherein
the first heat conduction link is formed of copper or aluminum.

10. The probe station device of claim 7, wherein
the first heat conduction link is formed of one of a single or a plurality of wire rod(s), a braided wire made of wire rods, or a stranded wire having a twisted shape.

11. The probe station device of claim 6, further comprising:
a bridge configured to connect the first supporter to the second supporter.

12. The probe station device of claim 11, wherein
the bridge is configured to support the side wall of the first chamber.

13. The probe station device of claim 11, wherein
the bridge is provided in plurality along the circumference of the sample stage, centered on the sample stage.

14. The probe station device of claim 6, wherein
the connector is provided in plurality along the inner wall of the second chamber.

15. The probe station device of claim 14, wherein the second supporter comprises:
a supporter body supported by the side wall of the first chamber; and
a plurality of supporter protrusions formed to extend from the supporter body toward the second chamber.

16. The probe station device of claim 15, wherein
each of the plurality of supporter protrusions passes between two adjacent connectors among the plurality of connectors.

17. The probe station device of claim 2, further comprising:
a plurality of supporter holes formed through the first supporter or the second supporter.

18. The probe station device of claim 17, wherein
the plurality of supporter holes is formed in a first direction, which is a height direction of a side wall of the first chamber, or formed in a second direction intersecting the first direction.

19. The probe station device of claim 17, wherein
a shape of a supporter hole formed through the first supporter is different from a shape of a supporter hole formed through the second supporter.

20. The probe station device of claim 1, wherein
the vibration reduction member is a damper or a bellows.

21. The probe station device of claim 1, further comprising:
an optical table disposed on a ground and configured to support the second chamber,
wherein the sample stage, the first chamber, the second chamber, and the optical table are connected to each other.

22. A probe station device comprising:
a sample stage on which a specimen is placed;
a refrigerator disposed below the sample stage and configured to control temperature of the sample stage;
a mounting portion disposed below the refrigerator and supported by a ground;
a stage supporter connected to the mounting portion and configured to support the sample stage;
a first chamber surrounding an outside of the sample stage;
a second chamber configured to maintain a vacuum state inside and surround an outside of the first chamber; and
a vibration reduction member configured to connect the refrigerator to the second chamber,
wherein the sample stage is capable of receiving a load of the mounting portion through the stage supporter.
